(19) United States
(12) Patent Application Publication
(10) Pub. No.: US 2026/0066026 A1
(43) Pub. Date: Mar. 5, 2026

(54) MEMORY PACKAGES WITH ADDITIONAL DIE WITH BUILT-IN SELF-TEST CIRCUITRY

(71) Applicant: Micron Technology, Inc., Boise, ID (US)

(72) Inventors: Matthew A. Prather, Boise, ID (US); Randall J. Rooney, Boise, ID (US); Navid Lashkarian, Pleasanton, CA (US); Anthony D. Veches, Boise, ID (US); Sujeet Ayyapureddi, Boise, ID (US)

(73) Assignee: Micron Technology, Inc., Boise, ID (US)

(21) Appl. No.: 19/300,495

(22) Filed: Aug. 14, 2025

Related U.S. Application Data
(60) Provisional application No. 63/689,068, filed on Aug. 30, 2024.

(51) Int. Cl. G11C 29/36; G11C 29/00; G11C 29/44; G11C 29/52

(52) U.S. Cl. CPC G11C 29/36; G11C 29/4401; G11C 29/52; G11C 29/76; G11C 2029/3602

(57) ABSTRACT

A memory package may include multiple memory devices and a additional die in some examples. The memory package may be included on a memory module. The memory module may include multiple memory packages. The additional die may include components that reduce or eliminate a number of components on the memory module. In some embodiments, the additional die includes memory built-in self-test (mBIST) circuitry for performing mBIST procedures on memory arrays on the multiple memory devices. The mBIST circuitry can supplement or replace mBIST circuitry on the multiple memory devices.

### CROSS-REFERENCE TO RELATED APPLICATION(S)

This application claims the benefit of U.S. Provisional Patent Application No. 63/689,068, filed on Aug. 30, 2024, and titled “Memory Packages with Buffer Die and Modules with Same.” The aforementioned application is incorporated herein by reference, in its entirety, for any purpose.

### BACKGROUND

Semiconductor memory devices are widely used in various electronic devices such as computers, wireless communication devices, cameras, digital displays, and the like. Some memory devices, such as a dynamic random-access memory (DRAM), include memory cells that may be arranged in addressable groups (e.g., rows or columns) within a memory array. Information may be stored in the memory cells, typically as single bit of information as either a logical high (e.g., a “1”) or a logical low (e.g., a “0”). When a memory controller receives a request to access a row or a column of memory cells, such as when performing a read or write operation, the memory controller may activate access to the row and/or column of memory cells. However, due to manufacturing errors and/or failures, certain memory cells may be defective. The ability to test for these errors and/or other defects in the memory device is desirable.

### BRIEF DESCRIPTION OF THE DRAWINGS

Non-limiting and non-exhaustive examples are described with reference to the following Figures. The elements of the drawings are not necessarily to scale relative to each other.

FIG. 1 illustrates a block diagram of at least a portion of an example system according to an embodiment of the disclosure;

FIG. 2 illustrates an example of a multi-die device according to an embodiment of the disclosure;

FIG. 3 illustrates another example of a multi-die device according to an embodiment of the disclosure;

FIG. 4 illustrates a block diagram of an example semiconductor device according to an embodiment of the disclosure;

FIG. 5 illustrates a block diagram of a portion of an example memory package 500 according to an embodiment of the disclosure;

FIG. 6 illustrates a block diagram of an example additional die according to an embodiment of the disclosure; and

FIG. 7 illustrates a flowchart of an example method according to an embodiment of the disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory cells of memory devices, such as DRAMs, static RAMs (SRAMs), flash memories, or the like, can experience defects leading to errors and/or failures. For example, rows containing defective memory cells may generally be referred to as defective rows. The defective rows may be incapable of storing information and/or may become otherwise inaccessible to the memory device. Memory testing techniques that employ testers that are external to the memory device may not be practical and/or provide inadequate results. Built-in self-test (BIST) circuits can be used for manufacturing and/or production testing of memory arrays. Additionally, one or more memory BIST (mBIST) circuits may be used for diagnostics and debugging during normal and/or power on operations. However, including the mBIST circuit(s) on the memory die can increase the number of components on the memory die and/or the size of the memory die.

Additionally, after a memory device is packaged, the memory device can be tested to identify defective memory cells. The addresses for memory cells that are mapped or assigned to defective memory cells can be remapped to non-defective memory cells (i.e., functional) so that the memory device can still be effective. For example, a memory array may generally include a number of additional rows of memory, which may generally be referred to as redundant memory. During a repair operation, a row address associated with a defective row may be redirected or remapped so that the row address is associated with one of the redundant rows instead. The remapped addresses may be stored in non-volatile storage in the memory device. For example, the memory device may include one or more fuse arrays that can include fuses (and/or anti-fuses) which may have state that can be permanently changed (e.g., when the fuse/anti-fuse is “blown”). The state of the fuses/anti-fuses in the fuse bank may, in part, determine which addresses are associated with which rows of memory.

The number of memory cells in the redundant memory is fixed and typically cannot be changed after the memory device is designed or packaged. Additionally, the information stored in the fuses or anti-fuses is fixed and cannot be changed once the fuses or anti-fuses are blown. Due to these limitations, some memory devices increase the amount of redundant memory in a memory array, which can result in unused memory cells in the redundant memory. In some instances, the additional redundant memory can increase the size of the memory array.

Embodiments of a memory package disclosed herein can include one or more memory devices and at least one additional die. The one or more memory devices may be stacked on each other to produce a stacked memory package. One or more memory packages may be included on a memory module. The additional die can include components that facilitate communication with a controller, a host system, and/or between memory packages. In some embodiments, the additional die may include components for providing built-in self-testing of the memory devices. The mBIST circuits on the additional die can supplement the mBIST circuits on each memory device, which may increase testing capabilities of memory packages. The mBIST circuits on the additional die may replace at least a portion of the mBIST circuits on each memory device, which may reduce the number of components on the memory devices and/or reduce the size of the memory devices. In some embodiments, the mBIST circuits on the additional die may replace the mBIST circuits on each memory device, which can reduce the number of components on and/or the size of the memory devices and/or may enable the memory arrays on multiple memory devices to be tested concurrently or at select times using the same mBIST circuitry. In some embodiments, the additional die may be a buffer die, but other embodiments are not limited to this implementation. The additional die may be any die or additional die in the memory package. For example, an additional memory device may be included in a memory package, where the mBIST circuit(s) on the additional memory device are used for mBIST procedures.

In some embodiments, the additional die may include components for providing redundant storage that can be used to remap the addresses for defective memory cells. The redundant storage on the additional die can supplement (e.g., add additional redundant storage) the redundant memory in the memory array, which may increase yields for memory packages. The redundant storage on the additional die may replace a portion of the redundant memory in the memory array, which may reduce the size of the redundant memory and/or the memory array. In some embodiments, the redundant storage on the additional die may replace the redundant memory in the memory array, which can enable more of the memory cells in the memory array to be used for data storage.

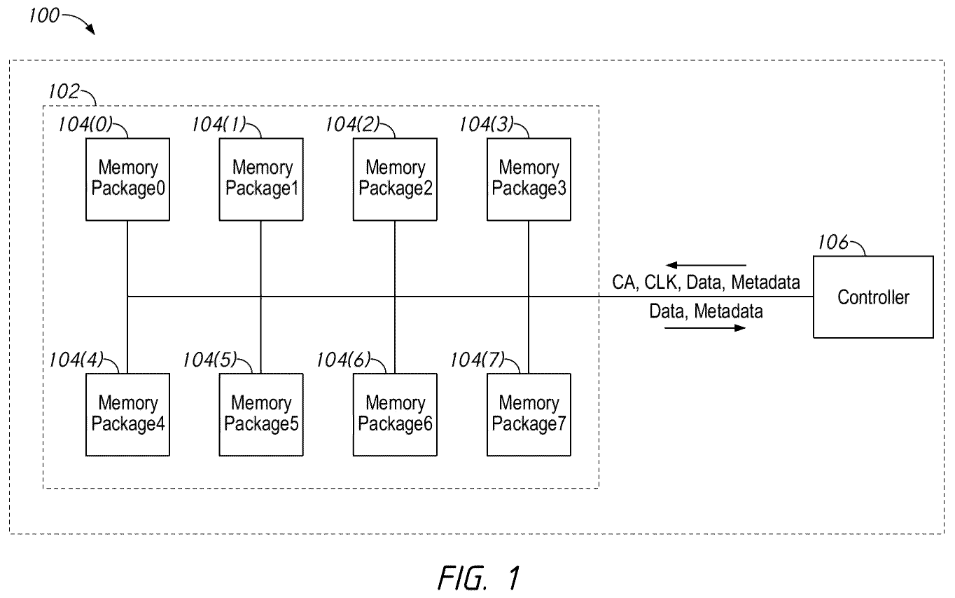

FIG. 1 illustrates a block diagram of at least a portion of an example system 100 according to an embodiment of the disclosure. For example, the system 100 can be a computing system. The system 100 includes a memory module 102 and a controller 106 in communication with the memory module 102. In some embodiments, the controller 106 may be included in a processor (not shown) or in communication with a processor. The memory module 102 may include one or more memory packages. In the embodiment shown in FIG. 1, there are eight memory packages 104(0)-104(7). However, in other embodiments, there may be more or fewer memory packages (e.g., one device, two devices, four devices, sixteen devices). In certain embodiments, the memory module 102 may be a dual in-line memory module (DIMM). In other embodiments, the components shown in FIG. 1 may represent only half of the DIMM (e.g., one of the two channels). In other words, the memory module 102 may include sixteen memory packages.

According to an embodiment, each memory package 104(0)-104(7) may include a additional die and one or more memory devices (also referred to herein as memory dies). The additional die may include components that facilitate communication with the controller 106 and/or host system. In some embodiments, the additional die may include components that facilitate communication between memory packages 104(0)-104(7). The memory devices can be stacked on the additional die in some examples, although other embodiments are not limited to this configuration.

The controller 106 can provide signals such as commands, addresses, clock signals and/or data (e.g., data, metadata, or both) to one or more of the memory packages 104(0)-104(7) and receive signals such as data, metadata, or both from one or more of the memory packages 104(0)-104(7). According to some embodiments, the controller 106 may provide and receive signals from a memory die via the additional die. In some embodiments, the memory packages 104(0)-104(7) may be x16 or x32 memory devices. That is, either sixteen (16) or thirty-two (32) DQ terminals (e.g., pins) may be active. In some embodiments, the memory packages 104(0)-104(7) may support both x16 and x32 operations. In certain embodiments, whether the memory packages 104(0)-104(7) operate in x4 or x8 mode may be based, at least in part, on values stored in mode registers (not shown) of the memory packages 104(0)-104(7). In some embodiments, the memory packages 104(0)-104(7) may be x4, x8, or x64 memory packages.

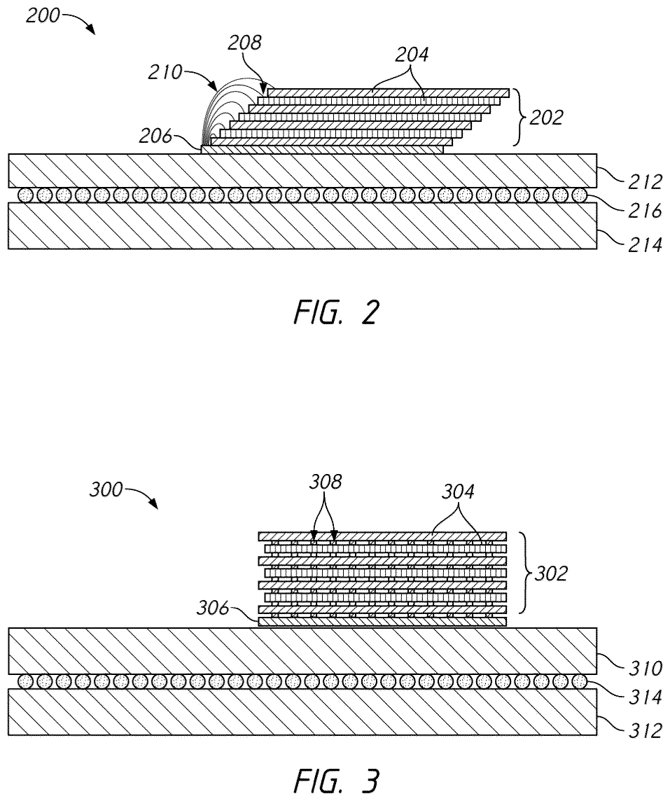

FIG. 2 illustrates an example of a multi-die device 200 according to an embodiment of the disclosure. The multi-die device 200 may include a stack 202 of memory devices 204 stacked on a additional die 206. Other embodiments are not limited to the particular number of memory devices 204 shown in FIG. 2. For example, the stack 202 may include one to sixteen memory devices 204. Further, while one additional die 206 is shown in FIG. 2, in some embodiments, there may be multiple additional dies 206 per stack 202. For example, the stack 202 can include two additional dies 206. In some embodiments, the stack 202 may be included in one or more memory packages (e.g., one or more of the memory packages 104(0)-104(7) of FIG. 1).

The memory devices 204 and the additional die 206 may be stacked in a staggered manner, providing a “shingle-stack” configuration for the stack 202 as shown in FIG. 2. However, the memory devices 204 and the additional die 206 may be stacked in other arrangements, such as a staggered configuration. The memory devices 204 and/or the additional die 206 may be attached to one another. In some embodiments, the memory devices 204 are attached to one another by an adhesive epoxy.

The memory devices 204 and/or the additional die 206 may include a pad formation area, a peripheral circuit area, and memory cell array areas that include memory cells, signal lines and circuits (not shown). Example circuits and signal lines include, but are not limited to, sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 204 and/or the additional die 206.

The pad formation area may include bond pads (not shown) disposed along one or more edges of the memory devices 204 and/or the additional die 206. The bond pads may be coupled to the terminals of the memory devices 204 and/or the additional die 206 and represent external terminals of the memory devices 204 and/or the additional die 206. For example, the bond pads may include data terminals, command and address terminals, clock terminals, and/or power supply terminals.

Circuits included in the memory cell array area and/or circuits of the peripheral circuit area may be coupled to one or more bond pads included in the pad formation area. Various circuits of the memory devices 204 and/or the additional die 206 may be coupled to the terminals. Conductive structures may be used to couple the terminals to one or more of the bond pads. As a result, the circuits coupled to the terminals are also coupled to the bond pads. The conductive structures may extend from locations of the terminals included in the memory cell array area and/or the peripheral circuit area to the pad formation area.

The memory devices 204 may be offset from one another to allow edge regions 208 of the memory devices 204 to be exposed. The exposed edge regions 208 may include the bond pads to which conductors 210 may be coupled. In some embodiments of the disclosure, the bond pads of the edge regions 208 may be conductive pads. The bond pads may be coupled to terminals of the respective memory device 204. In some embodiments, the conductors 210 are bond wires. While the conductors 210 in FIG. 2 are shown coupling all of the memory devices 204 to the additional die 206, the conductors 210 may be coupled in other configurations. For example, the conductors 210 may couple adjacent memory devices 204 to one another, and the lowest or bottom memory device 204 may be coupled to the additional die 206 by the conductors 210 in a “daisy chain” configuration.

The stack 202 may be attached to a substrate 212. For example, the stack 202 may be attached to the substrate 212 by an adhesive epoxy. The substrate 212 may be an interposer, a printed circuit board, or another type of substrate. The substrate 212 may include conductive signal lines to route signals along the substrate 212, for example, to and from the memory devices 204 and/or the additional die 206. The substrate 212 can be electrically coupled to the additional die 206 through electrical connectors (not shown), such as a flip chip ball grid array and/or wire bonding.

Other circuits may also be attached to the substrate 212 and coupled to the conductive signal lines of the substrate 212. The other circuits attached to the substrate 212 may be coupled, for example, to the memory devices 204 and/or the additional die 206 through the conductive signal lines of the substrate 212 and through conductors coupled to the conductive signal lines and the bond pads of the memory devices 204 and/or the additional die 206. In some embodiments, the substrate 212 may be included in a memory module (e.g., the memory module 102 of FIG. 1).

The substrate 212 can be coupled to another substrate 214 through conductive connectors 216. Although the conductive connectors 216 are shown as a ball grid array, other embodiments are not limited to this configuration. The substrate 214 may be any type of substrate. For example, the substrate 214 may be a package substrate.

FIG. 3 illustrates another example of a multi-die device 300 according to an embodiment of the disclosure. The multi-die device 300 may include a stack 302 of memory devices 304 stacked on a additional die 306. Other embodiments are not limited to the particular number of memory devices 304 in the stack 302 shown in FIG. 3. For example, the stack 302 may include one to sixteen memory devices 304. Further, while one additional die 306 is shown in FIG. 3, other embodiments can include multiple additional dies 306 per stack 302. For example, the stack 302 may include two additional dies 306. In some embodiments, the stack 302 may be included in one or more memory packages (e.g., the memory packages 104(0)-104(7)).

Similar to the embodiment of FIG. 2, the memory devices 304 and/or the additional die 306 may include a pad formation area, a peripheral circuit area, and memory cell array areas (not shown) that include memory cells, signal lines and circuits. For example, the circuits and the signal lines can include sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 304 and/or the additional die 306.

The memory devices 304 and the additional die 306 may be stacked in an aligned manner, such that the edges of the memory devices 304 are substantially aligned. When the additional die 306 is a similar dimension to the memory devices 304, the additional die 306 may be substantially aligned with the memory devices 304 as well, as shown in FIG. 3. However, the memory devices 304 and the additional die 306 may be stacked in other configurations such as a staggered configuration.

In contrast to the stack 202 shown in FIG. 2, the memory devices 304 and/or the additional die 306 are electrically coupled to one another by through silicon vias (TSVs) 308. In some embodiments, instead of or in addition to pad formation areas, the memory devices 304 and/or the additional die 306 may include TSV formation areas. The memory devices 304 and/or the additional die 306 may be physically attached to one another by additional mechanisms (e.g., not just the TSVs). In some embodiments, the memory devices 304 and the additional die 306 are attached to one another by an adhesive epoxy.

The stack 302 may be attached to a substrate 310. For example, the stack 302 may be attached to the substrate 310 by an adhesive epoxy. The substrate 310 may be an interposer, a printed circuit board, or another type of substrate. The substrate 310 may include conductive signal lines to route signals along the substrate 310, for example, to and from the memory devices 304 and/or the additional die 306. Other circuits may also be attached to the substrate 310 and coupled to the conductive signal lines of the substrate 310. As a result, the other circuits attached to the substrate 310 may be electrically coupled, for example, to the memory devices 304 and/or the additional die 306. In some embodiments, the substrate 310 may be included in a memory module (e.g., the memory module 102 of FIG. 1).

The substrate 310 can be coupled to another substrate 312 through conductive connectors 314. Although the conductive connectors 314 are shown as a ball grid array, other embodiments are not limited to this configuration. The substrate 312 may be any type of substrate. For example, the substrate 312 may be a package substrate.

In some embodiments, the memory devices 204, 304 and/or the additional die 206, 306 may include redundant memory. In certain embodiments, the additional die 206, 306 is a memory device substantially similar to the memory devices 204, 304. In some embodiments, the memory devices 204, 304 may have certain logic circuits disabled and/or bypassed, and the additional die 206, 306 has such logic circuits enabled and acts as a “target” or “master” die. In some embodiments, the additional die 206, 306 is a different device with different components than the memory devices 204, 304. According to embodiments of the present disclosure, the additional die 206, 306 may include buffers for buffering and/or arranging data received from the memory devices 204, 304 prior to providing to a controller and arranging data received from the controller prior to providing to the memory devices 204, 304.

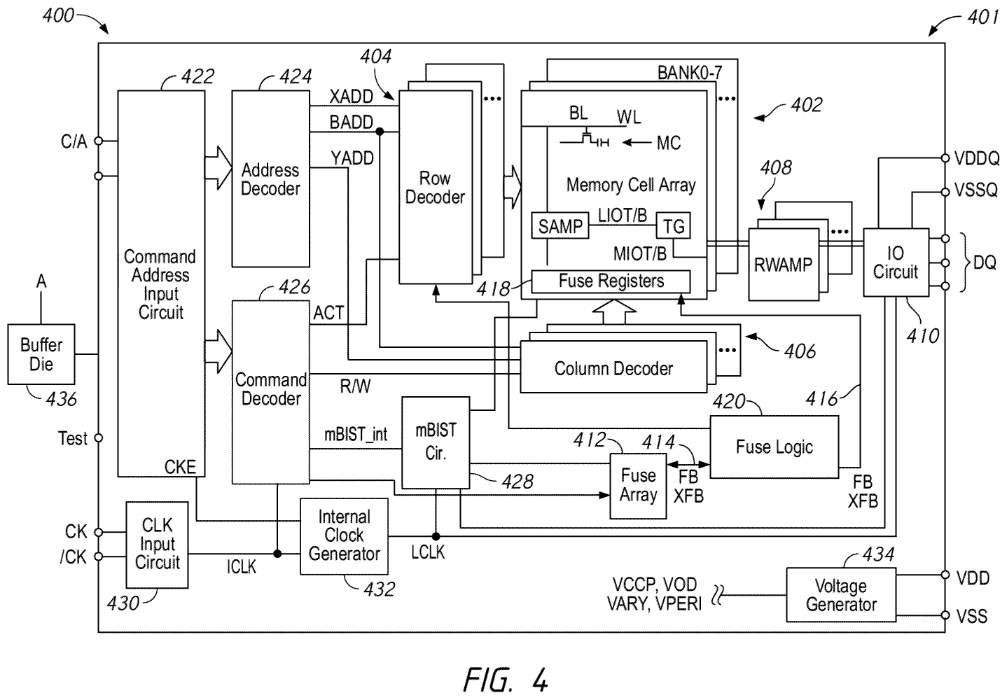

FIG. 4 illustrates a block diagram of an example semiconductor device 400 according to an embodiment of the disclosure. The semiconductor device 400 may include a memory device 401. The memory device 401 can include, without limitation, a dynamic random-access memory (DRAM), a double data rate (DDR) memory, a DDR5 or a DDR6 memory device, or other type of memory. In certain embodiments, each memory package 104(0)-104(7) of FIG. 1 can include one or more semiconductor devices 400. In some embodiments, the memory devices 204 of FIG. 2 and/or the memory devices 304 of FIG. 3 may each include the memory device 401.

The memory device 401 includes a memory array 402. The memory array 402 includes a plurality of memory banks BANK0-7. More or fewer memory banks may be included in the memory array 402 of other embodiments. In some embodiments, the memory banks may be arranged into bank groups. For example, a memory device may include sixteen or thirty-two total memory banks that are divided into two, four, eight or sixteen bank groups with two banks or four banks per bank group.

Each memory bank BANK0-7 includes a plurality of word lines WL, a plurality of bit lines BL and /BL (collectively referred to as BL), and a plurality of memory cells MC arranged at intersections of the plurality of word lines WL and the plurality of bit lines BL. The selection of the word lines WL is performed by a row decoder 404 and the selection of the bit lines BL is performed by a column decoder 406. In the embodiment of FIG. 4, the row decoder 404 includes a respective row decoder for each memory bank and the column decoder 406 includes a respective column decoder for each memory bank.

The bit lines are coupled to a respective sense amplifier (SAMP). Read data from the bit line BL is amplified by the sense amplifier SAMP and transferred to one or more read/write amplifiers 408 over complementary local data lines (LIOT/B), transfer gate (TG), and complementary main data lines (MIOT/B). Conversely, write data outputted from the one or more read/write amplifiers 408 is transferred to the sense amplifier SAMP over the complementary main data lines MIOT/B, the transfer gate TG, and the complementary local data lines LIOT/B, and written in the memory cell MC coupled to the bit line BL. The one or more read/write amplifiers (RWAMP) 408 may be coupled to an input/output (IO) circuit 410. The input/output circuit 410 can be coupled to one or more external terminals of the semiconductor device 400.

The memory device 401 can also include a fuse array 412, which contains a plurality of non-volatile storage elements that may store information about addresses in the memory array 402 (e.g., row repair information, column repair information). For example, the fuse array 412 can include fuses and/or anti-fuses. Each fuse may be in a first state where it is conductive until the fuse is ‘blown’ to make the fuse insulating instead. Each anti-fuse may be in a first state which is non-conductive until the anti-fuse is blown to make the anti-fuse conductive instead. Each fuse/anti-fuse may permanently change when it is blown. Each fuse/anti-fuse may be considered to be a bit, which is in one state before it is blown, and permanently in a second state after it's blown. For example, a fuse may represent a logical low before it is blown and a logical high after it is blown, while an anti-fuse may represent a logical high before it is blown and a logical low after it is blown. It should be understood that discussions of fuses as used herein may generally refer to either fuses or anti-fuses and that embodiments may use fuses, anti-fuses, or a combination thereof in the fuse array 412.

Specific groups of fuses/anti-fuses may be represented by a fuse bank address (FBA), which may specify the physical location of each of the fuses/anti-fuses in the group within the fuse array 412. The group of fuses/anti-fuses associated with a particular FBA may in turn encode an address associated with one or more memory cells of the memory array 402. For example, the state of a group of fuses/anti-fuses may represent a row address XADD or a column address YADD. FBAs can be provided to the fuse array 412 on a fuse bus 414 and in response, the address information in the fuse array 412 may be ‘scanned’ out along a fuse bus 416 to fuse registers 418. Each of the fuse registers 418 may be associated with a particular word line of the memory array 402. In some embodiments, the redundant rows/columns of the memory array 402 (e.g., the rows/columns designated for use in repair operations) may be associated with one of the fuse registers 418. The address stored in a given group of fuses/anti-fuses (e.g., a group specified by an FBA) may be scanned out from the fuse array 412 along the fuse buses 414, 416 and latched by a particular fuse register 418. A fuse logic circuit 420 may determine which address broadcast along the fuse bus 416 is latched in which fuse register 418. In this manner, an address stored in the fuse array 412 may be associated with a particular row or column of the memory array 402. When an incoming memory address matches the address stored in the fuse registers 418, it may then direct access commands to the memory row/column associated with that fuse register 418.

The fuse registers 418 may each contain a number of fuse latches, each of which stores a bit of the stored memory row or memory bank address. Since row addresses XADD and column addresses YADD may be different lengths, the fuse registers 418 associated with redundant rows may have a different number of fuse latches than the fuse registers 418 associated with redundant columns. Each of the fuse registers 418 may be coupled to a fuse match circuit (not shown), which compares the incoming memory row address as part of an access operation to the address stored in the fuse register 418 to determine if there is a match. If there is a match, the redundant memory row associated with the fuse register 418 may be activated.

Some components of the match circuits, as well as other control logic of the fuse registers 418 may be shared between multiple fuse registers 418. For example, in some embodiments, match circuits may be shared by a number of different fuse registers 418. In some embodiments, a dynamic logic circuit may manage which of the fuse registers 418 coupled to a match circuit is active to provide the address stored in that fuse registers 418 for a comparison operation to determine if an accessed memory line address matches the stored address. In some embodiments, the dynamic logic circuit may also manage timing of the comparison operation.

The semiconductor device 400 may employ a plurality of external terminals that include command and address (C/A) terminals coupled to a command/address bus to receive command and address signals, clock terminals to receive clock signals CK and /CK, data terminals DQ to provide data, and power supply terminals VDD, VPP, VSS, VDDQ, and VSSQ. In one embodiment, VDD, VPP, VDDQ may be power supply potential terminals and VSSQ and VSS may be ground reference terminals. The C/A terminals may be supplied with memory addresses from, for example, a host or a controller (e.g., the controller 106 of FIG. 1). The memory addresses supplied to the C/A terminals are transferred, via a command/address input circuit 422, to an address decoder 424. The address decoder 424 receives the address signals and supplies a decoded row address signal XADD to the row decoder 404, and a decoded column address signal YADD to the column decoder 406. The address decoder 424 also receives the bank address signal BADD and supplies the bank address signal to the row decoder 404 and the column decoder 406.

The C/A terminals may further be supplied with command signals from, for example, the host or the controller. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The command signals may be provided as internal command signals to a command decoder 426 via the command/address input circuit 422. The command decoder 426 includes circuits to decode the internal command signals to generate various internal signals and commands for performing operations, for example, a row activation signal (ACT) to select a word line. Another example may be providing internal signals to enable circuits for performing operations, such as control signals to enable signal input buffers that receive clock signals.

The C/A terminals may receive an access command which is a read command. When a read command is received, and a bank address, the row address, and a column address are timely supplied as part of the read operation, read data is read from memory cells in the memory array 402 corresponding to the row address and column address. For example, the row decoder 404 may access the word line associated with the fuse register 418 that stores an address which matches XADD. The read command is received by the command decoder 426, which provides internal commands so that read data from the memory array 402 is provided to the read/write amplifiers 408. The row decoder 404 may match the address XADD to an address stored in the fuse register 418, and then may access the physical row associated with that row fuse register 418. The read data is output to outside from the data terminals DQ via the input/output circuit 410.

The C/A terminals may receive an access command which is a write command. When the write command is received, and a bank address, the row address, and a column address are timely supplied as part of the write operation, and write data supplied through the DQ terminals is written to a memory cell in the memory array 402 corresponding to the row address and column address. The write command is received by the command decoder 426, which provides internal commands so that the write data is received by data receivers in the input/output circuit 410. The row decoder 404 may match the address XADD to an address stored in the fuse registers 418, and then access the physical row associated with that row fuse register 418. Write clocks may also be provided to the external clock terminals for timing the receipt of the write data by the data receivers of the input/output circuit 410. The write data is supplied via the input/output circuit 410 to the read/write amplifiers 408, and by the read/write amplifiers 408 to the memory array 402 to be written into the memory cell MC.

The memory device 401 may further include mBIST circuitry 428 configured to carry out self-testing operations. For example, the mBIST circuitry 428 may include one or more mBIST circuits, such as a test pattern generator, a comparator, built-in self-repair (BISR) circuitry, and/or other circuitry. The mBIST circuitry 428 may perform self-tests on the memory array 402 and/or other memory components of the memory device 401 to determine if the memory device 401 is operating properly. The mBIST circuitry 428 may perform self-tests automatically, responsive to a command provided to the command address input circuit 422, and/or a test signal provided to a TEST terminal (signal line(s) coupling TEST terminal to mBIST circuitry and possible other components omitted for simplicity). In some embodiments, the test signal may be provided by a host or a controller, such as the controller 106 of FIG. 1. After the self-test, the mBIST circuitry 428 may provide a result signal indicating whether the memory device 401 is operating properly or not. The result signal can be provided to the controller or the host. In some embodiments, the result signal may be provided to BISR circuitry, which may make repairs to the memory device 401 subject to the type of repair and the availability of repair elements. For example, the BISR circuitry may repair defects in the memory array 402 using the fuse array 412 and the fuse logic 420.

The clock terminals are supplied with external clocks CK and/CK that are provided to a clock input circuit 430. The external clocks may be complementary differential signals. When enabled, input buffers (not shown) included in the clock input circuit 430 pass the external clock signals. For example, an input buffer passes the CK and/CK signals when enabled by a CKE signal from the command/address input circuit 422. The clock input circuit 430 may use the external clock signals passed by the enabled input buffers to generate an internal clock ICLK. The ICLK clock is provided to the command decoder 426 and to an internal clock generator 432. The internal clock generator 432 provides various internal clocks LCLK based on the ICLK clock. The LCLK clocks may be used for timing operations of various internal circuits. The internal data clocks LCLK are provided to the input/output circuit 410 to time operation of circuits included in the input/output circuit 410, for example, to data receivers to time the receipt of write data.

The power supply terminals are supplied with potentials VDD, VDDQ, and VPP. The potentials VDD and VPP are supplied to an internal voltage generator circuit 434, and the potential VDDQ is supplied to the input/output circuit 410. The internal voltage generator circuit 434 generates various internal potentials VCCP, VOD, VARY, VPERI. The internal potential VCCP is mainly used in the row decoder 404, the internal potentials VOD and VARY are mainly used in the sense amplifiers included in the memory array 402, and the internal potential VPERI is used in many other circuit blocks.

The power supply terminals are also supplied with potentials VSSQ and VSS, which are reference potentials (e.g., ground) provided to the input/output circuit 410 and the internal power voltage generator circuit 434, respectively. The potentials VDDQ and VSSQ supplied to the power supply terminals may be the same potentials as the potentials VDD, VPP and VSS supplied to the power supply terminals in an embodiment of the disclosure. The potentials VDDQ and VSSQ supplied to the power supply terminals may be different potentials from the potentials VDD, VPP and VSS supplied to the power supply terminals in another embodiment of the disclosure. The potentials VDDQ and VSSQ are used for the input/output circuit 410 so that power supply noise generated by the input/output circuit 410 does not propagate to the other circuit blocks.

The semiconductor device 400 may also include a additional (Add.) die 436. The additional die 436 can receive the memory addresses (A) from the host or the controller. As will be described in more detail later, the additional die 436 may include various components, such as mBIST circuitry and optionally redundant storage. The redundant storge can be used in repair operations for defective memory cells.

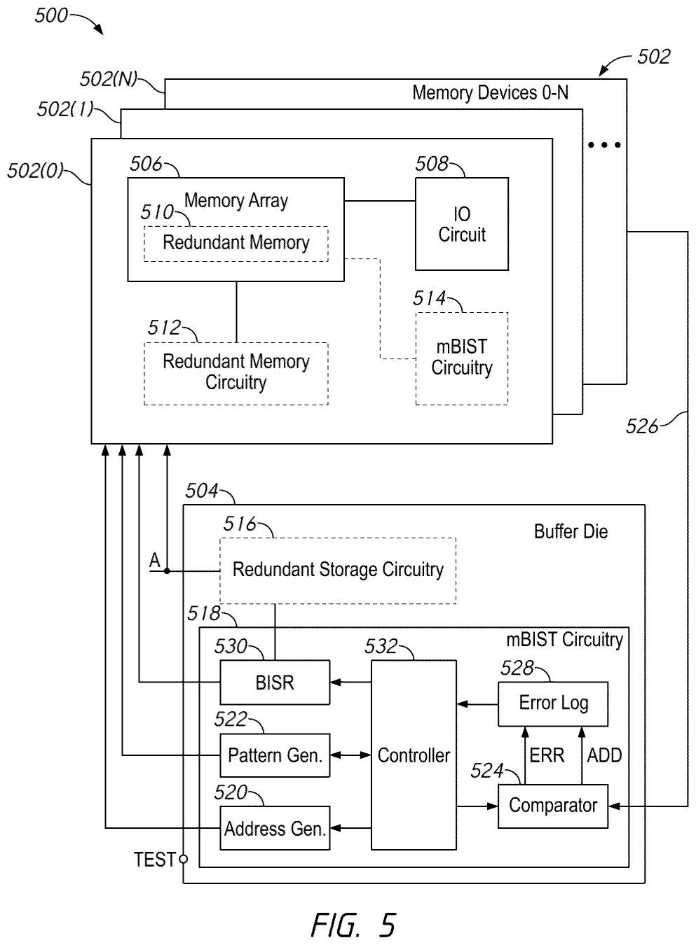

FIG. 5 illustrates a block diagram of a portion of an example memory package 500 according to an embodiment of the disclosure. The memory package 500 includes a plurality of memory devices (0-N) 502 and a additional die 504. More or fewer memory devices 502 may be included in the memory package 500 of other embodiments. In some embodiments, the memory package 500 may be implemented as the multi-die device 200 of FIG. 2 and/or the multi-die device 300 of FIG. 3. Each memory device can, in certain embodiments, include the memory device 401 of FIG. 4.

FIG. 5 is described in conjunction with one memory device 502(0). However, the description applies to each of the plurality of memory devices 502(0)-502(N). The memory device 502(0) may include one or more memory arrays (collectively memory array 506) and an input/output circuit 508. The memory device 502(0) may include optional redundant memory 510, optional redundant memory circuitry 512, and/or optional mBIST circuitry 514. The memory device 502(0) can include additional components, such as some or all of the components shown in the memory device 401 of FIG. 4. For example, the memory device 502(0) may include a command/address input circuit 422, an address decoder 424, a command decoder 426, a row decoder 404, a column decoder 406, and read/write amplifiers 408. Because FIG. 5 is described in conjunction with a built-in self-test operation, the additional components of the memory device 502(0) are omitted for brevity.

The memory device 502(0) may optionally include redundant memory 510 and redundant memory circuitry 512. In one embodiment, the redundant memory 510 is additional rows of memory cells and fuse registers and the redundant memory circuitry 512 includes a fuse array and fuse logic. For example, in some embodiments, the redundant memory circuitry 512 may include fuse array 412 and/or fuse logic 414. The redundant memory 510 can be used for repair operations. As described earlier, data associated with one or more addresses in the memory array 506 that are associated with defective memory cells are remapped to addresses in the redundant memory 510 such that memory cells in the redundant memory 510 are accessed instead of the defective memory cells. Accordingly, data may be read from or written to the memory cells in the redundant memory 510 instead of the defective memory cells in the memory array 506.

The memory device 502(0) may optionally include mBIST circuitry 514. The mBIST circuitry 514 may include one or more mBIST circuits, such as a test pattern generator, a comparator, built-in self-repair (BISR) circuitry, and/or other circuitry. In one embodiment, the mBIST circuitry 514 can include some or all of the components shown in the mBIST circuitry 518 of the additional die 504. The mBIST circuitry 514 may perform some or all of memory test operations (also referred to herein as an mBIST procedure) on the memory array 506 and/or other memory components of the memory device 502(0) to determine if the memory device 502(0) is operating properly.

The additional die 504 may optionally include a redundant storage circuitry 516. The redundant storage circuitry 516 may include redundant storage for repair operations. The redundant storage in the additional die may be in addition to, in place of, or as a supplement to the redundant memory 510 in the memory device 502(0). In some embodiments, the memory device 502(0) and the redundant storage circuitry 516 both receive addresses (A) for the memory array 506.

The additional die 504 can include mBIST circuitry 518. The mBIST circuitry 518 is configured to run one or more procedures of an mBIST procedure on the memory array 506 to identify defective memory cells in the memory array 506 and to perform repair operations for the defective memory cells. In the illustrated embodiment, the mBIST circuitry 518 includes an address generator circuit 520, a pattern generator circuit 522, a comparator circuit 524, an error log 528, BISR circuitry 530, and a controller 532. Other embodiments may include additional, different, or fewer components in mBIST circuitry.

The address generator circuit 520 is configured to generate addresses in the memory array 506 for an mBIST procedure. In one embodiment, the address generator circuit 520 generates sequential addresses in the memory array 506. Based on the addresses provided by the address generator circuit 520, the pattern generator circuit 522 is configured to provide a pattern of bits to the input/output circuit 508 on the memory device 502(0), where the pattern of bits is written to the memory cells in the memory array 506 (a “write pattern”) during the mBIST procedure. The pattern of bits may be all zeros, all ones, a checkerboard pattern, or any other pattern. In the example embodiment of FIG. 4, the addresses provided by the address generator circuit 520 may be received by the command address input circuit 422, the address decoder 424, the row decoder 404, and the column decoder 406, and the write pattern can be received by the input/output circuit 410 and the read/write amplifiers 408 and written to the memory array 402 based on the addresses.

The write pattern is read from the memory array 506 and received by the comparator circuit 524 as a read pattern via the input/output circuit 508 and signal line 526. The write pattern is also provided to the comparator circuit 524 and functions as an expected output pattern. In the example embodiment of FIG. 4, the addresses provided by the address generator circuit 520 may be received by the command address input circuit 422, the address decoder 424, the row decoder 404, and the column decoder 406, and the read pattern can be read from the memory array 402 based on the addresses. The read pattern is provided to the DQ terminals via the read/write amplifiers 408 and the input/output circuit 410.

The comparator circuit 524 is configured to compare the read pattern with the write pattern and to determine if there are one or more mismatches or errors between the read and write patterns. When an error does not occur, the comparator circuit 524 outputs an error signal ERR at a first signal level (e.g., a low or “0”). When an error occurs, the comparator circuit 524 outputs the error signal ERR at a second signal level (e.g., a high or a “1”) and information associated with the error is stored in the error log 528. For example, the information associated with the error can include the address in the memory array 506 that is associated with the error. In one embodiment, the error log 528 can be reported to a host or a controller, such as the controller 106 of FIG. 1.

In another embodiment, the error log 528 may be provided to the BISR circuitry 530. The BISR circuitry 530 can include circuits and logic that can be used to perform repair operations associated with the memory array 506. When the memory device 502(0) includes the redundant memory 510 and the redundant memory circuitry 512, the BISR circuitry 530 may be configured to store the address associated with the error in the redundant memory circuitry 512, which can map the address to a remapped address. For example, one or more fuses/anti-fuses may be blown in the redundant memory circuitry 512 to store the address. Data associated with the address may be stored in the redundant memory 510 on the memory device 502(0) based on the remapped address. When the redundant memory 510 and the redundant memory circuitry 512 are omitted from the memory device 502(0), the BISR circuitry 530 may be configured to store the address in the redundant storage circuitry 516, which is configured to map the address associated with the error to a remapped address.

The mBIST circuitry 518 on the additional die 504 can include the controller 532. In some embodiments, the controller 532 is configured to communicate with the address generator circuit 520, the pattern generator circuit 522, the comparator circuit 524, the error log 528, and the BISR circuitry 530. The controller 532 can receive and decode instructions for performing mBIST procedures on the memory array 506. The instructions may be received from the memory device 502(0), from an external host or controller, from a command provided to a command address input circuit, and/or from a test signal provided to a TEST terminal (signal line(s) omitted for simplicity). For example, the controller 106 of FIG. 1 may provide the instructions, the command address input circuit 422 of FIG. 4 can provide the instructions, and/or a test signal may be provided to the TEST terminal shown in FIG. 4 and/or the TEST terminal shown in FIG. 5. In some embodiments, the controller 532 can provide instructions for the repair and/or the isolation of memory cells in the memory array 506 that have failed the mBIST procedure.

In some embodiments, some, but not all, of the components in the mBIST circuitry 514 on the memory device 502(0) may be omitted and the performance of the mBIST procedures is distributed between the mBIST circuitry 518 on the additional die 504 and the mBIST circuitry 514 on the memory device 502(0). For example, in one embodiment, the mBIST circuitry 514 on the memory device 502(0) can include an address generator circuit, a pattern generator circuit, and a comparator circuit that are configured to provide addresses for a write pattern to be written to the memory array 506 and a read pattern to be read from the memory array, and to compare the write pattern with the read pattern, while the mBIST circuitry 518 on the additional die 504 may include an error log, BISR circuitry, and a controller that are configured to store information associated with the errors between the write and the read patterns and to perform the repair operations for the errors. Different distributions of the components in the mBIST circuitry 514 and the mBIST circuitry 518 can be implemented in other embodiments.

In certain embodiments, a additional die may be fabricated using a fabrication process that is used to fabricate DRAM memory devices (also referred to as a DRAM process). However, the DRAM process may be limiting in some embodiments due at least in part to certain types of components in the memory device. For example, capacitors can limit the fabrication process because some fabrication steps may stress the DRAM capacitors. Further, DRAM processes may require additional manufacturing steps, which increases the cost of manufacturing. In some instances, a DRAM process may produce components that operate at slower speeds.

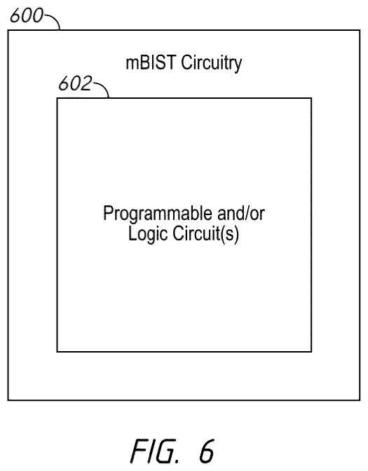

In other embodiments, a additional die may be fabricated using a complementary metal-oxide-semiconductor (CMOS) fabrication process (also referred to herein as a CMOS process). FIG. 6 illustrates a block diagram of an example additional die 600 according to an embodiment of the disclosure. The additional die 600 includes programmable circuits and/or logic circuits 602 that are fabricated using a CMOS process. In a non-limiting example, a CMOS process can be used to fabricate transistors, resistors, diodes, capacitors, logic gates, and integrated circuits such as a microprocessors and microcontrollers. The programmable circuits can, in some embodiments, be programmed with firmware, enabling the functionality of the mBIST circuitry to be improved and/or to provide additional or more complex functionality. In some instances, CMOS components may be simpler to manufacture and can produce components that operate at faster speeds. Further, CMOS processes may be more scalable compared to DRAM processes, allowing for continuous improvements in performance and efficiency.

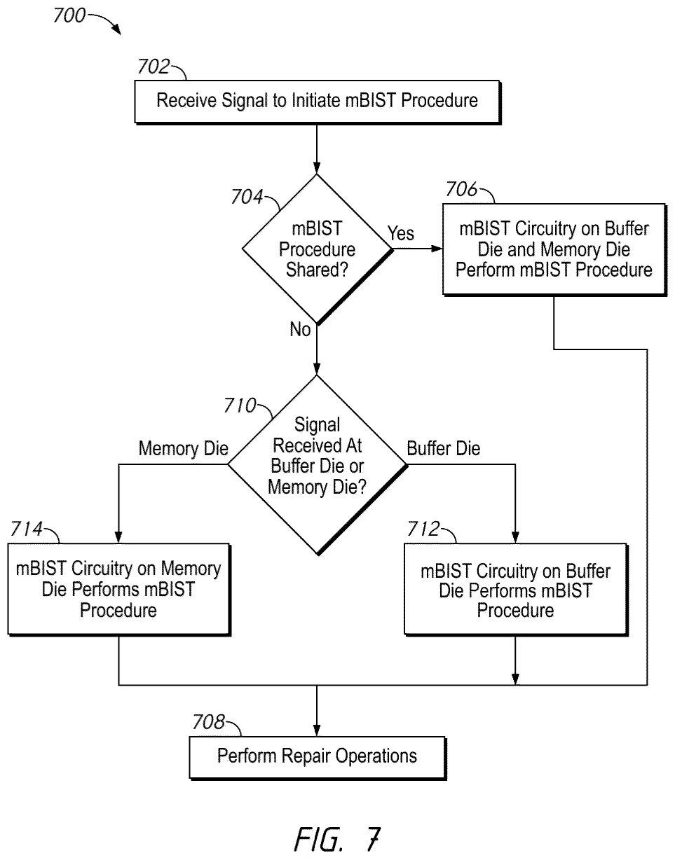

FIG. 7 illustrates a flowchart of an example method 700 according to an embodiment of the disclosure. Initially, at block 702, a signal to initiate an mBIST procedure on a memory array on a memory die is received. The signal can be received, for example, from an external host or a controller, a memory die, a TEST terminal on the additional die and/or on the memory die, and/or from a command provided to a memory die. At block 704, a determination is made as to whether the mBIST procedure is shared or distributed between the memory die and the additional die. In other words, a determination is made as to whether the mBIST circuitry on the additional die will perform some of the operations in the mBIST procedure and the mBIST circuitry on the memory die will perform other operations in the mBIST procedure. For example, the mBIST circuitry on the memory die may generate addresses for the mBIST procedure, write a write pattern to the memory array on the memory die, read a read pattern from the memory array, and compare the write pattern with the read pattern, while the mBIST circuitry on the additional die can receive information on errors detected during the comparison of the read and the write patterns and perform operations (or cause operations to be performed) to repair the defective memory cells associated with the errors.

Based on a determination at block 704 that the mBIST procedure is shared, the method passes to block 706 where the mBIST circuitry on the additional die and on the memory die perform the mBIST procedure. At block 708, a repair operation can be performed by the mBIST circuitry on the additional die (e.g., BISR circuitry 530) and/or the memory die for each error identified during the mBIST procedure. For example, the mBIST circuitry on the memory die can map addresses associated with the errors to remapped addresses such that data is stored in a redundant memory of the memory array on the memory die. Additionally or alternatively, the mBIST circuitry on the additional die may map addresses associated with the errors to remapped addresses such that data is stored in either a redundant memory of the memory array on the memory die and/or in redundant storage on the additional die.

Based on a determination at block 704 that the mBIST procedure is not shared, the method continues at block 710 where a determination is made as to whether the signal is received at the additional die or at the memory die. Based on a determination that the signal is received at the additional die, the method passes to block 712 where the mBIST procedure is performed by the mBIST circuitry on the additional die. The method continues at block 708, where a repair operation can be performed by the mBIST circuitry on the additional die for each error identified during the mBIST procedure. For example, the mBIST circuitry on the additional die can map addresses associated with the errors to remapped addresses such that data is stored in either a redundant memory of the memory array on the memory die and/or in redundant storage on the additional die.

Based on a determination at block 710 that the signal is received at the memory die, the method continues at block 714 where the mBIST procedure is performed by the mBIST circuitry on the memory die. The method continues at block 708, where a repair operation can be performed by the mBIST circuitry on the memory die for each error identified during the mBIST procedure. For example, the mBIST circuitry on the memory die may map addresses associated with the errors to remapped addresses such that data is stored in a redundant memory of the memory array on the memory die.

The systems, methods, and apparatuses disclosed herein may allow for memory packages with one or more additional dies to replace or supplement mBIST circuitry on a memory die, which may increase testing capabilities of memory packages. The mBIST circuits on the additional die may replace at least a portion of the mBIST circuits on each memory device, which may reduce the number of components on the memory devices and/or reduce the size of the memory devices. In some embodiments, the mBIST circuits on the additional die may replace the mBIST circuits on each memory die, which can reduce the number of components on and/or the size of the memory dies and/or may enable the memory arrays on multiple memory devices to be tested concurrently or at select times using the same mBIST circuitry.

The foregoing description, for purposes of explanation, uses specific nomenclature to provide a thorough understanding of the described embodiments. However, it will be apparent to one skilled in the art that the specific details are not required to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An apparatus, comprising:
a memory device comprising a memory array; and
a additional die in communication with the memory device, the additional die comprising:
a pattern generator circuit configured to provide a write pattern to the memory array for a memory built-in self-test (mBIST) procedure, the write pattern comprising a first pattern of bits; and
a comparator circuit configured to receive a read pattern from the memory cells in the memory array and to compare the write pattern to the read pattern to determine an error between the read pattern and the write pattern, the read pattern comprising a second pattern of bits.

2. The apparatus of claim 1, wherein the additional die further comprises an error log configured to store information about the error.

3. The apparatus of claim 1, wherein the additional die further comprises built-in self-repair (BISR) circuitry configured to perform a repair operation for the error.

4. The apparatus of claim 1, wherein the additional die further comprises an address generator configured to generate addresses for the memory array for the mBIST procedure.

5. The apparatus of claim 1, wherein the memory device further comprises mBIST circuitry configured to perform an mBIST procedure on the memory array.

6. The apparatus of claim 1, wherein the memory device and the additional die are included in a stacked memory package.

7. The apparatus of claim 1, wherein the memory device comprises:
redundant memory configured to store data associated with one or more defective memory cells in the memory array; and
redundant memory circuitry configured to store remapped addresses for the redundant memory.

8. The apparatus of claim 1, wherein the memory device and the additional die are included in a memory module.

9. The apparatus of claim 1, wherein the additional die is fabricated using a complementary metal-oxide-semiconductor process.

10. A memory package, comprising:
a plurality of memory devices, each memory device in the plurality of memory devices comprising a memory array; and
a additional die in communication with the plurality of memory devices, the additional die comprising:
memory built-in self-test (mBIST) circuitry configured to perform an mBIST procedure.

11. The memory package of claim 10, wherein the mBIST circuitry comprises:
a pattern generator circuit configured to provide a write pattern to each memory array for the mBIST procedure, the write pattern comprising a first pattern of bits; and
a comparator circuit configured to receive a read pattern from the memory cells in each memory array and to compare the write pattern to the read pattern to determine an error between the read pattern and the write pattern, the read pattern comprising a second pattern of bits.

12. The memory package of claim 10, wherein the mBIST circuitry comprises an address generator circuit configured to provide addresses for each memory array for one or more mBIST procedures.

13. The memory package of claim 10, wherein the mBIST circuitry comprises an error log configured to store information about each error.

14. The memory package of claim 10, wherein the mBIST circuitry comprises built-in self-repair (BISR) circuitry configured to perform a repair operation for each error.

15. The memory package of claim 10, wherein the memory package is one of a plurality of memory packages included in a memory module.

16. The memory package of claim 10, wherein the memory device comprises:
redundant memory configured to store data associated with one or more defective memory cells in the memory array; and
redundant memory circuitry configured to store remapped addresses for the redundant memory.

17. The memory package of claim 10, wherein each memory device of the plurality of memory devices comprises mBIST circuitry configured to perform an mBIST procedure.

18. A method, comprising:
receiving a signal to initiate a memory built-in self-test (mBIST) procedure for a memory array on a memory device;
performing, by mBIST circuitry on a additional die, at least a portion of the mBIST procedure based on the additional die receiving the signal.

19. The method of claim 18, wherein:
the mBIST circuitry on the additional die performs a first portion of the mBIST procedure; and
the remaining portion of the mBIST procedure is performed by mBIST circuitry on the memory die.

20. The method of claim 19, further comprising performing a repair operation for each error identified during the mBIST procedure.

21. The method of claim 18, wherein:
the mBIST circuitry on the additional die performs the mBIST procedure based on the additional die receiving the signal; and
the method further comprises performing, by mBIST circuitry on the memory die, the mBIST procedure based on the memory die receiving the signal.

22. The method of claim 21, further comprising performing a repair operation for each error identified during the mBIST procedure.

23. The method of claim 18, wherein the signal is received from a controller.
